(19) United States
(12) Patent Application Publication
(10) Pub. No.: US 2022/0284155 A1
(43) Pub. Date: Sep. 8, 2022

(54) ROCK MASS ENGINEERING CROSS-SCALE SIMULATION CALCULATION METHOD BASED ON REV ALL-REGION COVERAGE

(71) Applicant: SHANDONG UNIVERSITY, Jinan, Shandong (CN)

(72) Inventors: Shucai LI, Jinan (CN); Zongqing ZHOU, Jinan (CN); Liping LI, Jinan (CN); Chunjin LIN, Jinan (CN); Shaoshuai SHI, Jinan (CN); Chenglu GAO, Jinan (CN); Cheche WEI, Jinan (CN); Chengshun SHANG, Jinan (CN); Songsong BAI, Jinan (CN)

(73) Assignee: SHANDONG UNIVERSITY, Jinan, Shandong (CN)

(21) Appl. No.: 17/630,231

(22) PCT Filed: Oct. 22, 2020
(86) PCT No.: PCT/CN2020/122785

§ 371 Date: Jan. 26, 2022

(30) Foreign Application Priority Data
Apr. 30, 2020 (CN) 202010363419.9

(51) Int. Cl. G06F 30/23; G06F 30/13

(52) U.S. Cl. CPC G06F 30/23; G06F 30/13

(57) ABSTRACT

A rock mass engineering cross-scale simulation calculation method based on REV all-region coverage, including establishing a rock mass engineering scale calculation model of particles and joints, and providing the model with particle material parameters and contact parameters; performing model region division dividing the model into multiple finite elements, and performing all-region coverage and mesh division using the finite elements, wherein a volume of the finite element is equal to a representative elementary volume of a REV model; and applying boundary conditions, calculating force and motion information of finite element nodes using a continuous medium method, obtaining a failed finite element according to the node force and motion information, and calculating motion information of particles of the REV model in the failed finite element using a discontinuous medium method. According to the calculation method, the calculation efficiency is improved, and the accuracy of calculation results is ensured.

### TECHNICAL FIELD

The present invention relates to the technical field of simulation calculation of rock masses and specifically relates to a rock mass engineering cross-scale simulation calculation method based on REV all-region coverage.

### BACKGROUND

Descriptions herein only provide background techniques related to the present invention and do not necessarily constitute the related art.

Since the construction scale of underground engineering and tunnel engineering is constantly increased, site conditions become more and more complex, and resulting engineering problems also become more and more difficult to solve. These geotechnical engineering problems often have high anisotropy, non-uniformity, and discontinuity, and mechanical analysis on these problems can be hardly achieved by using conventional analytical methods; however, due to disadvantages such as high cost and long period, physical test methods cannot be applied in a wide range or on a large scale. Due to low cost and good operability, numerical simulation methods are widely used.

With the advancement of computer technologies to a petaflop level or a higher level, numerical simulation theories and methods for solving geotechnical engineering problems are rapidly developed. Since a variety of numerical methods have been successfully applied, people's understanding of geotechnical engineering phenomena is deepened, and the development of geotechnical engineering is strongly promoted.

Existing numerical simulation methods are mainly classified into two types, including continuous medium methods and discontinuous medium methods. During research and simulation of geotechnical engineering problems, due to complex characteristics, laws of force transmission and microscopic mechanisms of deformation development can be hardly revealed essentially by using simulation methods based on continuous medium mechanics (such as a finite element method, a boundary element method, and a finite difference method). A discrete element method is a numerical simulation method based on discontinuous medium mechanics proposed by Cundall for the first time in 1971, which is characterized in that rock masses are regarded as discrete rigid or variable blocks cut by structural planes such as faults, joints, and fractures, Newton's equation of motion is established, and displacements of the blocks are obtained by using a difference scheme. Therefore, the discrete element method can be used for effectively simulating a deformation process of discrete particle combinations such as the rock masses, and complex derivation of a constitutive relation is avoided. Due to this characteristic, the discrete element method is widely applied in rock mechanics, soil mechanics, fluid mechanics, and other fields.

However, it is found by the inventor that when the discrete element method is used for performing engineering scale simulation calculation, millions, ten million or even more of particles are calculated, so that required calculation resources and time are inevitably increased exponentially, and calculation and analysis abilities are greatly challenged.

### SUMMARY

In order to overcome the shortcomings of the prior art, an objective of the present invention is to provide a rock mass engineering scale simulation calculation method. The simulation accuracy is ensured, and the calculation efficiency is improved.

To achieve the foregoing objective, the present invention uses the following technical solutions:

In a first aspect, an embodiment of the present invention provides a rock mass engineering cross-scale simulation calculation method based on REV all-region coverage, and the method includes:

establishing a rock mass engineering scale calculation model consisting of particles and having joints, and providing the rock mass calculation model with particle parameters, where the rock mass engineering scale calculation model is used for simulating mechanical behaviors;

performing region division on the rock mass engineering scale calculation model to divide the rock mass model into multiple finite elements, performing all-region coverage on the rock mass engineering scale calculation model by using the finite elements, and performing mesh division on the finite elements, where a volume of the finite element is equal to a representative elementary volume, namely, a volume of a REV model; and

applying boundary conditions to the rock mass engineering scale calculation model, calculating force and motion information of finite element nodes by using a continuous medium method, obtaining a failed finite element according to the force and motion information of the finite element nodes, and calculating motion information of particles of the REV model in the failed finite element by using a discontinuous medium method.

The present invention has the following beneficial effects:

1. According to the calculation method of the present invention, only the failed finite element is calculated by using the discontinuous medium method, and other finite elements are calculated by using the continuous medium method so that the number of elements that need to be calculated by using a discrete element method is reduced, the time required for traversal and calculation is shortened, and the calculation efficiency is improved.

2. According to the calculation method of the present invention, the volume of the finite element is the representative elementary volume, namely, the volume of the REV model, and the all-region coverage rock mass model based on characteristics of the representative elementary volume is constructed, so that the consistency of macro-mechanical properties and the accuracy of calculation results are ensured when the continuous medium method for calculation is converted into the mesoscopic discontinuous medium method for calculation.

### BRIEF DESCRIPTION OF THE DRAWINGS

The accompanying drawings that constitute a part of this application are used to provide a further understanding of the present invention. Exemplary embodiments of the present invention and descriptions of the embodiments are used for describing the present invention and do not constitute any limitation to the present invention.

FIG. 1 is a schematic diagram of a whole calculation process in Embodiment 1 of the present invention;

FIG. 2 is a schematic diagram of a rock mass model in Embodiment 1 of the present invention;

FIG. 3 is a schematic diagram of samples of discrete element models in Embodiment 1 of the present invention;

FIG. 4 is a curve diagram showing a relationship between a size and a volume joint density of the discrete element models in Embodiment 1 of the present invention;

FIG. 5 is a curve diagram showing a relationship between a size and a volume joint number of the discrete element models in Embodiment 1 of the present invention;

FIG. 6 is a schematic diagram of the rock mass model divided into multiple finite elements in Embodiment 1 of the present invention; and

FIG. 7 is a schematic diagram showing the mesh division of the rock mass model divided into multiple finite elements in Embodiment 1 of the present invention.

### DETAILED DESCRIPTION

It should be noted that the following detailed descriptions are all exemplary, and are intended to provide further descriptions of the present invention. Unless otherwise specified, all technical and scientific terms used herein have the same meaning as commonly understood by a person of ordinary skill in the art to which the present invention belongs.

It should be noted that terms used herein are only for describing specific implementations and are not intended to limit exemplary implementations according to the present invention. As used herein, the singular form is also intended to include the plural form unless the context dictates otherwise. In addition, it should further be understood that terms “comprise” and/or “include” used in this specification indicate that there are features, steps, operations, devices, components, and/or combinations thereof.

As introduced in the background, when a discrete element method is used for performing engineering scale simulation calculation, millions, ten million, or even more particles are calculated, so that required calculation resources and time are inevitably increased exponentially, and calculation and analysis abilities are greatly challenged; in order to solve the problems above, the present application provides a rock mass engineering cross-scale simulation calculation method based on REV all-region coverage.

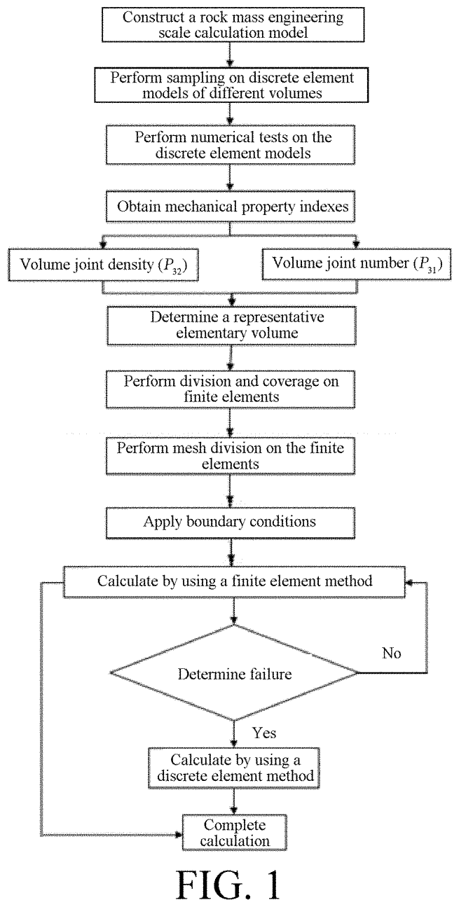

According to a typical implementation Embodiment 1 of the present application, as shown in FIG. 1, a rock mass engineering cross-scale simulation calculation method based on REV all-region coverage includes the following steps:

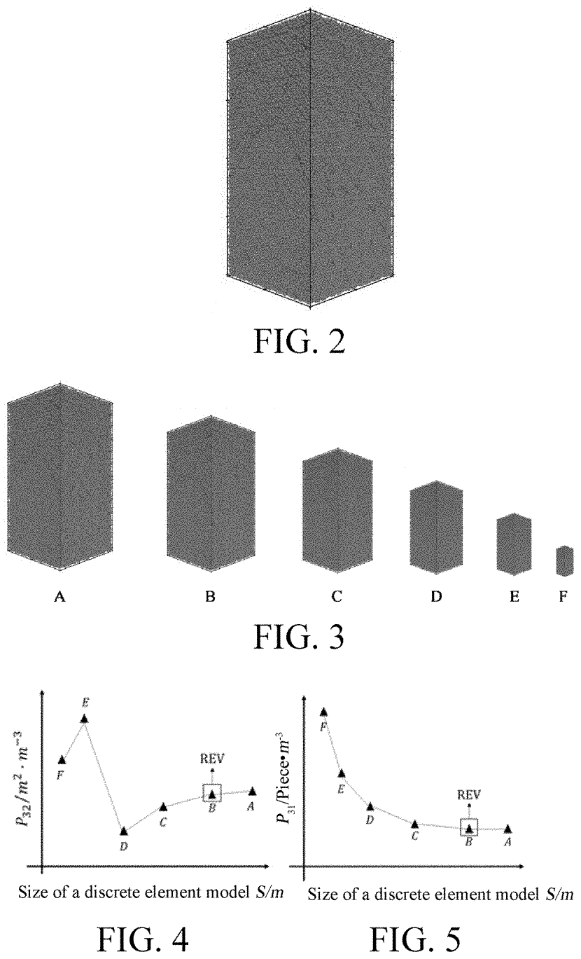

Step 1: as shown in FIG. 2, a rock mass engineering scale calculation model consisting of particles is established, and the rock mass engineering scale calculation model is provided with particle parameters including material parameters and contact parameters, the rock mass engineering scale calculation model is internally provided with joints and used for simulating mechanical behaviors of rock masses.

The particle material parameters include density, stiffness, friction coefficient, porosity, and particle size distribution, and the contact parameters include normal stiffness, tangential stiffness, bonding stiffness, and bonding spacing.

Step 2: region division is performed on the rock mass engineering scale calculation model to divide the rock mass model into multiple finite elements; all-region coverage is performed on the rock mass engineering scale calculation model by using the finite elements, and mesh division is performed on the finite elements, and a volume of the finite element is equal to a representative elementary volume (a volume of a REV model).

Step 2 specifically includes the following steps:

Step a: as shown in FIG. 3, sampling is performed on the rock mass model established in step 1 according to a set length, width, and height ratio, and discrete element models of different sizes and the same shape are established.

In this embodiment, six discrete element models respectively marked as A, B, C, D, E, and F from large to small, are established.

Step b: numerical tests are performed respectively on the six discrete element models obtained in step a to obtain a change law of rock mass property indexes of the discrete element model.

Step c: a minimum volume of the discrete element model when the set rock mass mechanical property indexes tend to be stable is selected as the representative elementary volume (REV).

The minimum volume of the discrete element model when the mechanical property indexes tend to be stable is the representative elementary volume of the elements (the volume of the REV model), REV refers to the minimum volume of a rock mass when the influence of structural planes on mechanical properties of the rock mass tends to be stable, the mechanical properties are changed with the volume when the volume of the rock mass is lower than REV, and the elements can be regarded as equivalent continuous media with REV as a basic element when the volume of the rock mass is higher than that of the REV model.

The mechanical property indexes of the rock mass include mechanical indexes, deformation indexes, and structural plane strength indexes. The mechanical indexes include uniaxial compression strength, triaxial compression strength, and the like; the deformation indexes include elastic modulus, Poisson's ratio, and the like; and the structural plane strength indexes include volume joint density (P₃₂), volume joint number (P₃₁) and the like. The structural plane strength indexes directly reflect a change law of a structural plane system with size and are the most direct indexes to determine REV. Therefore, in this embodiment, the volume joint density (P₃₂) and the volume joint number (P₃₁) are used as the indexes to determine the element volume.

As shown in FIG. 4 and FIG. 5, curve diagrams showing the volume joint density (P₃₂) and the volume joint number (P₃₁) of the six discrete element models are drawn, the horizontal axis represents the size of the discrete element models, the vertical axis represents the volume joint density (P₃₂) and the volume joint number (P₃₁). The volume joint density (P₃₂) and the volume joint number (P₃₁) of the six discrete element models tend to be stable from the discrete element model B, and therefore, the volume of the discrete element model B is the representative elementary volume.

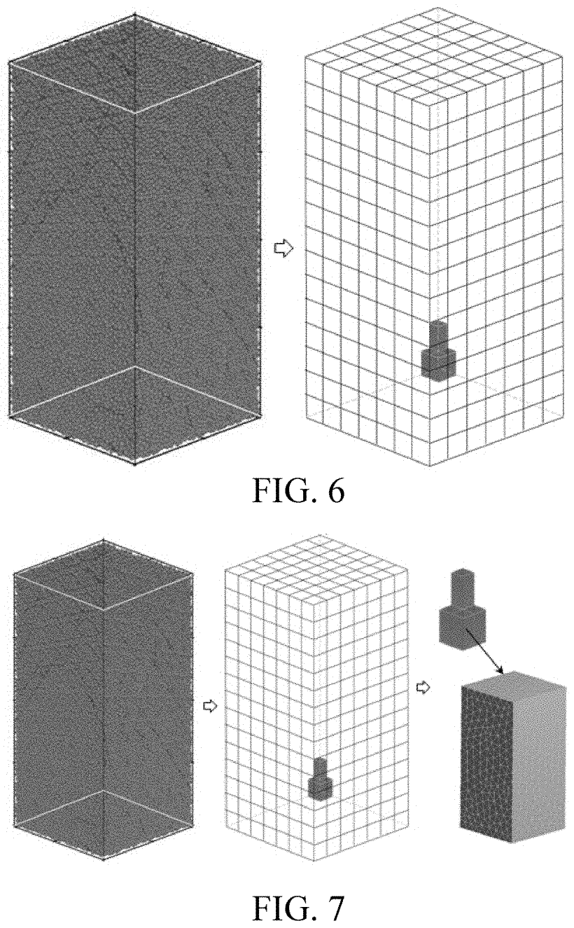

Step d: as shown in FIG. 6 and FIG. 7, the whole rock mass model is divided into multiple finite elements with REV attributes according to the representative elementary volume obtained in step c, and finite element mesh division is performed on the elements, namely all-region coverage is performed on the rock mass engineering scale calculation model by using the finite elements.

The volume of the divided finite elements is the minimum volume-representative elementary volume (REV) of the discrete element model when the mechanical property indexes of the rock mass tend to be stable, physical and mechanical properties of the rock mass can be characterized, and the accuracy of calculating the elements by using a discontinuous medium method is ensured.

Step 3: boundary conditions are applied to the rock mass engineering scale calculation model, force and motion information of finite element nodes is calculated by using a continuous medium method, a failed finite element is obtained according to the force and motion information of the finite element nodes, and force and motion information of particles of the REV model in the failed finite element is calculated by using the discontinuous medium method.

Through the steps above, a FEM-REV-DEM cross-scale calculation method in an engineering scale, a macroscopic scale, and a mesoscopic scale is established, and simulation calculation of a model including millions and ten million of particles is achieved.

Compared with a traditional simple discontinuous medium calculation method, only the failed element is calculated by using the discontinuous medium method in this embodiment, so that time required for traversal and calculation by using the discontinuous medium calculation method is shortened, and the calculation efficiency is greatly improved. According to the calculation method in this embodiment, the volume of the finite element is the representative elementary volume, and the all-region coverage rock mass model based on characteristics of the representative elementary volume is constructed, so that the consistency of macro-mechanical properties and the accuracy of calculation results are ensured when the continuous medium method for calculation is converted into the mesoscopic discontinuous medium method for calculation.

The boundary conditions are determined according to construction site conditions and are consistent with the site construction conditions.

An existing finite element method is used as the continuous medium method, the element nodes are used as finite element calculation nodes, the whole rock mass model is subjected to finite element analysis and calculation, the stress state of each element is tracked in real-time, and each element is subjected to stress-strain calculation by Hooke's law.

Calculation of a node resultant force is shown as:

F=Fₑ+F_{d}+F_{c} (1)

in the formula, F refers to node resultant force; Fₑ refers to node external force; F_{d} refers to node deformation force (contributed by element stress); and F_{c} refers to damping force.

A node movement calculation formula is shown as:

a=F/m,v=ΣaΔt

Δu=vΔt,u=ΣΔu (2)

in the formula, a refers to nodal acceleration; v refers to nodal speed; Δu refers to nodal displacement increment; u refers to total nodal displacement amount; m refers to nodal mass, and Δt refers to calculation time step. After alternate calculation based on the formulas (1) and (2), an explicit solution process of the finite elements can be realized.

The element stress and the node deformation forces are calculated by using an incremental method, information transmission of adjacent nodes can be realized by updating a strain matrix and node coordinates in real-time, and calculation of large displacement and deformation of the finite elements is realized.

The processes above are all calculation processes by using the existing finite element method and can be automatically performed by using finite element analysis software.

After motion information and force information of all the element nodes are subjected to finite element calculation, whether the elements undergo shear failure or tensile failure or not is determined based on a Mohr-Coulomb criterion and a maximum tensile stress criterion.

A specific method is as follows:

$$\begin{matrix}{f}^{s} = {σ}_{1} - {σ}_{3} {N}_{φ} + 2 c \sqrt{{N}_{φ}} \\ {f}^{t} = {σ}_{3} - T \\ h = {f}^{t} + {α}^{p} ( {σ}_{1} - {σ}^{p} )\end{matrix} \} \\ where \\ {N}_{φ} = \frac{1 + sin ( φ )}{1 - sin ( φ )} \\ {α}^{p} = \sqrt{1 + {N}_{φ}^{2}} + {N}_{φ} \\ {σ}^{p} = {TN}_{φ} - 2 c \sqrt{{N}_{φ}} \qquad ( 3 )$$

in the formula, σ₁ refers to maximum principal stress of the elements, σ₃ refers to minimum principal stress of the elements and can be calculated according to the force information of the element nodes obtained by using the finite element method, the minimum principal stress and the maximum principal stress can be automatically obtained by using the finite element software in the prior art, and a calculation method is not described in detail here; c, φ, and T refer to cohesion, internal friction angle and tensile strength respectively and can be calculated in advance in an experiment based on the material parameters used in the rock mass model, f^{s} refers to the compressive stress of the finite elements, f^{t} refers to a tensile stress of the finite elements, and h refers to shear stress of the finite elements.

The motion information (speed and displacement) and the force information of particles of the REV model in the failed finite element are calculated by using the discontinuous medium method, and an existing discrete element method is used as the discontinuous medium method.

The speeds and displacements of the particles in the failed finite element are obtained by using an interpolation calculation method based on the speed and displacement of the element nodes; preferably, 2-3 element nodes closest to a to-be-calculated particle are selected for interpolation calculation to obtain the speed and displacement of the to-be-calculated particle, so that the calculation time is shortened.

A method for calculating the speeds of the particles in the elements is shown as:

$${v}^{p} = {\sum }_{j = 1}^{{N}_{e}} {W}_{j} {v}_{j}^{e} \qquad ( 4 )$$

v^{p} refers to the speed of the to-be-calculated particle, Wⱼ refers to interpolation coefficient of a j-th element node for interpolation calculation, vⱼ^{e} refers to the speed of the j-th node for interpolation calculation, and Nₑ refers to the number of element nodes for interpolation calculation.

A method for calculating the displacements of the particles in the elements is shown as:

$${u}^{p} = {\sum }_{j = 1}^{{N}_{e}} {W}_{j} {u}_{j}^{e} \qquad ( 5 )$$

u^{p} refers to the speed of the to-be-calculated particle, Wⱼ refers to interpolation coefficient of a j-th element node for interpolation calculation, vⱼ^{e} refers to the speed of the j-th node for interpolation calculation, and Nₑ refers to the number of element nodes for interpolation calculation.

The existing discrete element method is used for calculating the force information of the particles in the elements and is not described in detail here.

According to the calculation method in this embodiment, macroscopic deformation of the rock mass model can be simulated by using the finite element method, small-scale fractures of the rock mass model can be simulated by using the discrete element method, and various simulation results are obtained.

The specific implementations of the present invention are described above concerning the accompanying drawings, but are not intended to limit the protection scope of the present invention. A person skilled in the art should understand that various modifications or deformations may be made without creative efforts based on the technical solutions of the present invention, and such modifications or deformations shall fall within the protection scope of the present invention.

What is claimed is:

1. A rock mass engineering cross-scale simulation calculation method based on REV all-region coverage, comprising: establishing a rock mass engineering scale calculation model, and providing the rock mass engineering scale calculation model with particle parameters; dividing the rock mass engineering scale calculation model into multiple finite elements, and performing mesh division on the finite elements, wherein a volume of the finite element is equal to a representative elementary volume, namely, a volume of a REV model; and applying boundary conditions to the rock mass engineering scale calculation model, calculating force and motion information of finite element nodes by using a continuous medium method, identifying a failure state of the finite elements, and calculating motion information of particles of the REV model in a failed finite element by using a discontinuous medium method.

2. The rock mass engineering cross-scale simulation calculation method based on REV all-region coverage according to claim 1, wherein a method for determining the representative elementary volume comprises:
step a: performing sampling on the established rock mass engineering scale calculation model according to a set length, width, and height ratio, and establishing multiple discrete element models of different sizes and the same shape;
step b: respectively performing numerical tests on the multiple discrete element models obtained in step a to obtain a change law of rock mass property indexes of the discrete element model; and
step c: selecting a volume of the discrete element model when set mechanical property indexes tend to be stable as the representative elementary volume.

3. The rock mass engineering cross-scale simulation calculation method based on REV all-region coverage according to claim 2, wherein in step c, the set mechanical property indexes comprise a volume joint density and a volume joint number.

4. The rock mass engineering cross-scale simulation calculation method based on REV all-region coverage according to claim 1, wherein a finite element method is used as the continuous medium method.

5. The rock mass engineering cross-scale simulation calculation method based on REV all-region coverage according to claim 1, wherein a discrete element method is used as the discontinuous medium method.

6. The rock mass engineering cross-scale simulation calculation method based on REV all-region coverage according to claim 1, wherein whether the finite elements are failed or not is determined by determining whether the finite elements undergo shear failure or tensile failure or not.

7. The rock mass engineering cross-scale simulation calculation method based on REV all-region coverage according to claim 6, wherein whether the finite elements undergo shear failure or tensile failure or not is determined based on a Mohr-Coulomb criterion and a maximum tensile stress criterion.

8. The rock mass engineering cross-scale simulation calculation method based on REV all-region coverage according to claim 7, wherein a method for determining whether the finite elements undergo brittle shear failure or brittle tensile failure or not specifically comprises: calculating a compressive stress f^{s} on the finite elements, a tensile stress f^{t} on the finite elements and a shear stress h on the finite elements;
when f^{s}≤0 and h≤0, determining that the elements undergo brittle shear failure; and when f^{t}≥0 and h>0, determining that the elements undergo brittle tensile failure.

9. The rock mass engineering cross-scale simulation calculation method based on REV all-region coverage according to claim 1, wherein speeds and displacements of the particles in the failed finite element are obtained by using an interpolation calculation method based on speeds and displacements of the finite element nodes.

10. The rock mass engineering cross-scale simulation calculation method based on REV all-region coverage according to claim 9, wherein 2-3 finite element nodes closest to a to-be-calculated particle are selected for interpolation calculation to obtain a speed and a displacement of the to-be-calculated particle.
